(19) United States
(12) Patent Application Publication
(10) Pub. No.: US 2024/0332331 A1
(43) Pub. Date: Oct. 3, 2024

(54) IMAGE SENSING DEVICE

(71) Applicant: SK hynix Inc., Icheon-si (KR)

(72) Inventor: Ho Young KWAK, Icheon-si (KR)

(21) Appl. No.: 18/508,570

(22) Filed: Nov. 14, 2023

(30) Foreign Application Priority Data
Mar. 28, 2023 (KR) 10-2023-0040363

(51) Int. Cl. H01L 27/146; H01L 23/538

(52) U.S. Cl. CPC H01L 27/1463; H01L 23/5384

(57) ABSTRACT

Image sensing devices are disclosed. In an embodiment, an image sensing device includes a semiconductor substrate including a first surface and a second surface facing or opposite to the first surface, and structured to include a pixel region in which photoelectric conversion elements are formed to correspond to unit pixels and a pad region that is located outside the pixel region while having an electrode pad, a pixel isolation pattern disposed between the photoelectric conversion elements in the semiconductor substrate, and a pad isolation pattern disposed between the pixel region and the pad region in the semiconductor substrate.

### PRIORITY CLAIM AND CROSS-REFERENCE TO RELATED APPLICATION

This patent document claims the priority and benefits of Korean patent application No. 10-2023-0040363, filed on Mar. 28, 2023, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

In an attempt to achieve the demands of high-resolution, high-speed image sensors, multi-layer image sensors have been developed.

### SUMMARY

Various embodiments of the disclosed technology relate to an image sensing device having an isolation structure with improved reliability.

In an embodiment of the disclosed technology, an image sensing device may include a semiconductor substrate including a first surface and a second surface facing or opposite to the first surface, and structured to include a pixel region in which photoelectric conversion elements are formed to correspond to unit pixels and a pad region that is located outside the pixel region while having an electrode pad, a pixel isolation pattern disposed between the photoelectric conversion elements in the semiconductor substrate, and a pad isolation pattern disposed between the pixel region and the pad region in the semiconductor substrate. The pad isolation pattern includes at least one first upper isolation pattern formed to extend from the first surface toward the second surface to have a same depth as the pixel isolation pattern and at least one second upper isolation pattern formed to extend from a bottom surface of the at least one first upper isolation pattern toward the second surface. An upper surface of the at least one second upper isolation pattern has a smaller width than the bottom surface of the at least one first upper isolation pattern.

In another embodiment of the disclosed technology, an image sensing device may include a semiconductor substrate structured to include a pixel region in which photoelectric conversion elements for photoelectric conversion of incident light are formed and a pad region that is located outside the pixel region while having an electrode pad, a pixel isolation pattern formed to vertically extend to a first depth while being disposed between the photoelectric conversion elements, and a pad isolation pattern formed to vertically extend to a second depth greater than the first depth while being disposed between the pixel region and the pad region, and formed to have a stepped shape at the first depth.

In another embodiment of the disclosed technology, an image sensing device may include a pixel region formed in a semiconductor substrate and including a plurality of unit pixels, each unit pixel including a photoelectric conversion element configured to detect incident light to generate photocharge carrying an image in the incident light, a pad region including an electrode pad and located outside the pixel region, a pixel isolation pattern disposed between the photoelectric conversion elements in the semiconductor substrate, and a pad isolation pattern disposed between the pixel region and the pad region in the semiconductor substrate, wherein the semiconductor substrate includes a first surface and a second surface opposite to the first surface, wherein the pad isolation pattern includes at least one first upper isolation pattern formed to extend from the first surface of the semiconductor substrate toward the second surface of the semiconductor substrate to have a same depth as the pixel isolation pattern, and at least one second upper isolation pattern formed to extend from a bottom surface of the least one first upper isolation pattern toward the second surface of the semiconductor substrate, wherein an upper surface of the at least one second upper isolation pattern has a smaller width than the bottom surface of the at least one first upper isolation pattern.

In another embodiment of the disclosed technology, an image sensing device may include a pixel region formed in a semiconductor substrate and including: photoelectric conversion elements configured to detect incident light to generate photo-charge carrying an image in the incident light; and a pad region including an electrode pad and located outside the pixel region, a pixel isolation pattern vertically extending to a first depth in the semiconductor substrate and disposed between the photoelectric conversion elements, and a pad isolation pattern vertically extending in the semiconductor substrate to a second depth greater than the first depth and disposed between the pixel region and the pad region, wherein the pad isolation pattern has a stepped shape at the first depth.

In another embodiment of the disclosed technology, an image sensing device may include an image sensing device may include a semiconductor including a first surface and a second surface facing or opposite to the first surface, and structured to include a pixel region in which photoelectric conversion elements are formed to correspond to unit pixels and a pad region located outside the pixel region while having an electrode pad; a pixel isolation pattern disposed between the photoelectric conversion elements in the semiconductor substrate; and a pad isolation pattern disposed between the pixel region and the pad region in the semiconductor substrate. The pad isolation pattern may include at least one first upper isolation pattern formed to extend from the first surface toward the second surface to the same depth as the pixel isolation pattern; and at least one second upper isolation pattern formed to extend from a bottom surface of each of the first upper isolation patterns toward the second surface, and formed such that an upper surface of each second upper isolation pattern has a smaller width than the bottom surface of each first upper isolation pattern.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

FIG. 1 is a block diagram illustrating an example of an image sensing device based on some implementations of the disclosed technology.

FIG. 2 is a perspective view schematically illustrating an example structure of an image sensing device based on some implementations of the disclosed technology.

FIG. 3 is a plan view illustrating an example of a planar arrangement structure of a first stacked structure arranged in the image sensing device shown in FIG. 2 based on some implementations of the disclosed technology.

FIG. 4 is a cross-sectional view illustrating an example of the first stacked structure taken along the line X-X′ shown in FIG. 3 based on some implementations of the disclosed technology.

FIG. 5 is an enlarged view illustrating an example of a partial region of a pad isolation pattern shown in FIG. 4 based on some implementations of the disclosed technology.

FIGS. 6A to 6D are cross-sectional views illustrating examples of a process for forming a pad isolation pattern shown in FIG. 4 based on some implementations of the disclosed technology.

FIG. 7 is a cross-sectional view illustrating an example structure of a pad isolation pattern based on some implementations of the disclosed technology.

FIG. 8 is a cross-sectional view illustrating an example structure of a pad isolation pattern based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device having an isolation structure with improved reliability. The disclosed technology provides various implementations of an image sensing device which can prevent progressive defects that may occur in a process of forming an isolation structure and subsequent processes thereof by improving the isolation structure.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

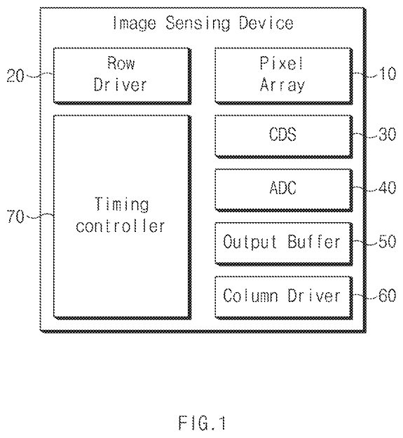

FIG. 1 is a block diagram illustrating an image sensing device based on some implementations of the disclosed technology.

Referring to FIG. 1, the image sensing device may include a pixel array 10, a row driver 20, a correlated double sampler (CDS) 30, an analog-digital converter (ADC) 40, an output buffer 50, a column driver 60 and a timing controller 70. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light, and a phase detection pixel that is structured to generate second electrical signals for calculating a phase difference between the images.

The pixel array 10 may include a plurality of unit pixels arranged in rows and columns. In one example, the plurality of unit pixels can be arranged in a two dimensional (2D) pixel array including rows and columns. In another example, the plurality of unit pixels can be arranged in a three dimensional (3D) pixel array. The plurality of unit pixels may convert an optical signal into an electrical signal on a unit pixel basis or a pixel group basis, where unit pixels in a pixel group share at least certain internal circuitry. The plurality of unit pixels may include a plurality of imaging pixels and a plurality of phase detection pixels. Each of the image pixels may generate an image signal acting as an electrical signal corresponding to a target object to be captured.

The pixel array 10 may receive driving signals (for example, a row selection signal, a reset signal, a transmission (or transfer) signal, etc.) from the row driver 20. Upon receiving the driving signal, the unit pixels may be activated to perform the operations corresponding to the row selection signal, the reset signal, and the transfer signal.

The row driver 20 may activate the pixel array 10 to perform certain operations on the unit pixels in the corresponding row based on control signals provided by controller circuitry such as the timing controller 70. In some implementations, the row driver 20 may select one or more pixel groups arranged in one or more rows of the pixel array 10. The row driver 20 may generate a row selection signal to select one or more rows from among the plurality of rows. The row driver 20 may sequentially enable the reset signal and the transfer signal for the unit pixels arranged in the selected row. The pixel signals generated by the unit pixels arranged in the selected row may be output to the correlated double sampler (CDS) 30.

The correlated double sampler (CDS) 30 may remove undesired offset values of the unit pixels using correlated double sampling. In one example, the correlated double sampler (CDS) 30 may remove the undesired offset values of the unit pixels by comparing output voltages of pixel signals (of the unit pixels) obtained before and after photo-charges generated by incident light are accumulated in the sensing node (i.e., a floating diffusion (FD) node). As a result, the CDS 30 may obtain a pixel signal generated only by the incident light without causing noise. In some implementations, upon receiving a clock signal from the timing controller 70, the CDS 30 may sequentially sample and hold voltage levels of the reference signal and the pixel signal, which are provided to each of a plurality of column lines from the pixel array 10. That is, the CDS 30 may sample and hold the voltage levels of the reference signal and the pixel signal which correspond to each of the columns of the pixel array 10. In some implementations, the CDS 30 may transfer the reference signal and the pixel signal of each of the columns as a correlate double sampling (CDS) signal to the ADC 40 based on control signals from the timing controller 70.

The ADC 40 is used to convert analog CDS signals received from the CDS 30 into digital signals. In some implementations, the ADC 40 may be implemented as a ramp-compare type ADC. The analog-to-digital converter (ADC) 40 may compare a ramp signal received from the timing controller 70 with the CDS signal received from the CDS 30, and may thus output a comparison signal indicating the result of comparison between the ramp signal and the CDS signal. The analog-to-digital converter (ADC) 40 may count a level transition time of the comparison signal in response to the ramp signal received from the timing controller 70, and may output a count value indicating the counted level transition time to the output buffer 50.

The output buffer 50 may temporarily store column-based image data provided from the ADC 40 based on control signals of the timing controller 70. The image data received from the ADC 40 may be temporarily stored in the output buffer 50 based on control signals of the timing controller 70. The output buffer 50 may provide an interface to compensate for data rate differences or transmission rate differences between the image sensing device and other devices.

The column driver 60 may select a column of the output buffer 50 upon receiving a control signal from the timing controller 70, and sequentially output the image data, which are temporarily stored in the selected column of the output buffer 50. In some implementations, upon receiving an address signal from the timing controller 70, the column driver 60 may generate a column selection signal based on the address signal, may select a column of the output buffer 50 using the column selection signal, and may control the image data received from the selected column of the output buffer 50 to be output as an output signal.

The timing controller 70 may generate signals for controlling operations of the row driver 20, the ADC 40, the output buffer 50 and the column driver 60. The timing controller 70 may provide the row driver 20, the column driver 60, the ADC 40, and the output buffer 50 with a clock signal required for the operations of the respective components of the image sensing device, a control signal for timing control, and address signals for selecting a row or column. In some implementations, the timing controller 70 may include a logic control circuit, a phase lock loop (PLL) circuit, a timing control circuit, a communication interface circuit and others.

In some implementations, the different circuits or modules in the image sensing device FIG. 1 may be all formed over or supported by a common silicon substrate. Such a design may limit the size of the pixel array 10 and thus the spatial imaging resolution of the imaging device. This patent document discloses image sensors by separating different parts of an imaging device into circuits on different stacked substrates to allow for a large pixel array 10 with a large number of imaging pixels and/or implementing larger size imaging pixels for the improved imaging resolution or imaging quality.

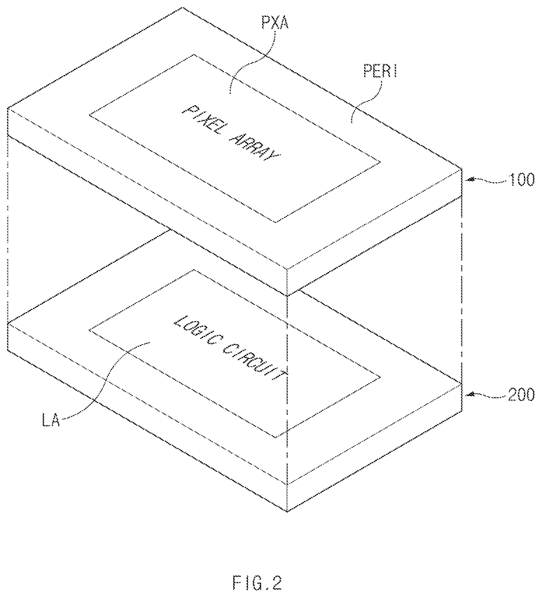

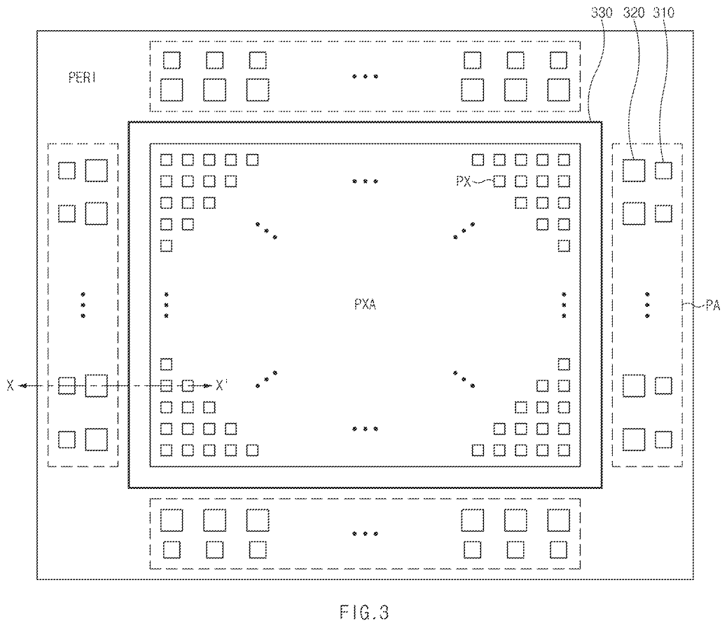

FIG. 2 is a perspective view schematically illustrating an example structure of an image sensing device based on some implementations of the disclosed technology using two stacked substrates for supporting various circuits in FIG. 1 on different substrates. FIG. 3 is a plan view illustrating an example of a planar arrangement structure of a first stacked structure arranged in the image sensing device shown in FIG. 2 based on some implementations of the disclosed technology.

Referring to FIGS. 2 and 3, the image sensing device may include a first stacked structure 100 and a second stacked structure 200.

The first stacked structure 100 may be disposed over the second stacked structure 200. The first stacked structure 100 may include a pixel region (PXA), in which the pixel array 10 shown in FIG. 1 is formed, and a peripheral region (PERI) located outside the pixel region (PXA).

The pixel region (PXA) may include a plurality of unit pixels (PXs) arranged in rows and columns. Each unit pixel (PX) may include a photoelectric conversion region, a color filter, a microlens, and a plurality of pixel transistors. In some implementations, the pixel region (PXA) may be disposed at a center portion of the first stacked structure 100.

The peripheral region (PERI) may include a pad region (PA) which includes electrode pads 320 for electrical connection to external device(s) and TSV structure 310 for electrically interconnecting the first stacked structure 100 and the second stacked structure 200. In some implementations, the peripheral region (PERI) may further a pad isolation pattern 330 disposed between the pixel region (PXA) and the pad region (PA) to isolate the pixel region (PXA) and the pad region (PA) from each other. In some implementations, the peripheral region (PERI) may be arranged to surround the pixel region (PXA).

The TSV structure 310 may be connected to the electrode pad 320 to electrically connect the first stack structure 100 and the second stack structure 200 to one or more external devices. Alternatively, the image sensing device may include through silicon vias (TSVs) configured to electrically interconnect the first stack structure 100 and the second stack structure 200 without being connected to the electrode pad 320.

The first stacked structure 100 may include a first substrate, and a first interconnect layer formed below a surface (e.g., a first front surface) facing the second stacked structure 200 on the first substrate. The first interconnect layer may include metal interconnects disposed in an interlayer insulation layer. The metal interconnects of the first interconnect layer may be electrically connected to the unit pixels (PXs) and the TSV structure 310.

The second stacked structure 200 may include a logic region (LA) in which logic circuits such as the row driver 20, the CDS 30, the ADC 40, the output buffer 50, the column driver 60, and the timing controller 70 shown in FIG. 1 are formed. The logic region (LA) may be disposed at a center portion of the second stacked structure 200. The logic region (LA) may include electronic circuitry (e.g., transistors) that can generate control signals to control operations of the unit pixels (PXs) and generate images by processing pixel signals output from the unit pixels (PXs).

The second stacked structure 200 may include a second substrate, and a second interconnect layer formed over a surface (e.g., a second front surface) facing the first stacked structure 100 on the second substrate. The first stacked structure 100 and the second stacked structure 200 may be stacked so that the first interconnect layer and the second interconnect layer are in contact with each other. The second interconnect layer may include a plurality of interconnects formed in an interlayer insulation layer. The interconnects of the second interconnect layer may be electrically connected to the electronic circuitry of the logic region (LA) and the TSV structure 310.

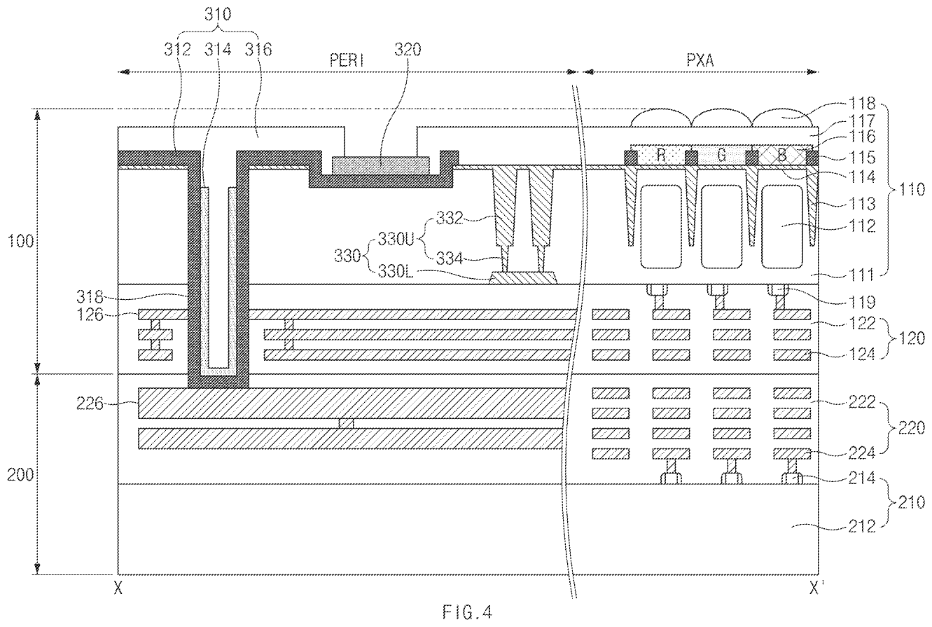

FIG. 4 is a cross-sectional view illustrating an example of the first stacked structure 100 taken along the line X-X′ shown in FIG. 3 based on some implementations of the disclosed technology.

Referring to FIG. 4, the image sensing device may include a first stacked structure 100 and a second stacked structure 200.

The first stacked structure 100 may include a first substrate layer 110 and a first interconnect layer 120. In some implementations, the second stacked structure 200 may include a second substrate layer 210 and a second interconnect layer 220. The first stacked structure 100 and the second stacked structure 200 may be stacked so that the first interconnect layer 120 and the second interconnect layer 220 are in contact with each other.

In the first stacked structure 100, the first substrate layer 110 may include a pixel region (PXA) and a peripheral region (PERI). The pixel region (PXA) may include a first substrate 111, at least one photoelectric conversion element 112, a pixel isolation pattern 113, an anti-reflection layer 114, a grid structure 115, color filters 116, and an over-coating layer 117, microlenses 118, and pixel transistors 119. The peripheral region (PERI) may include a TSV structure 310, an electrode pad 320, and a pad isolation pattern 330.

The first substrate 111 may include a first front surface and a first back surface opposite to the first front surface. The first back surface of the first substrate 111 may be a light reception surface upon which light is incident, and may be formed to have the grid structure 115, the color filters 116, the over-coating layer 117, and the microlenses 118 of the unit pixels (PXs). The first front surface of the first substrate 111 may be formed to have pixel transistors 119, and may be in contact with the first interconnect layer 120. In some implementations, the image sensing device may be a backside illuminated (BSI) image sensing device.

The first substrate 111 may include a semiconductor substrate. For example, the first substrate 111 may be a bulk-silicon substrate or a silicon-on-insulator (SOI) substrate. Alternatively, the first substrate 111 may be formed of or include an epitaxial layer formed over a base substrate.

The photoelectric conversion element 112 may detect incident light to generate photo-charges carrying an image in the incident light through photoelectric conversion of incident light received through the first back surface of the first substrate 111. The photoelectric conversion element 112 may be formed in the first substrate 111 to correspond to the unit pixels (PXs) within the pixel region (PXA). In some implementations, photo-charges generated by the photoelectric conversion element 112 may increase in proportion to the intensity of incident light. The photoelectric conversion element 112 may include a photodiode, a phototransistor, a photogate, a pinned photodiode, an organic photodiode, a quantum dot, or a combination thereof, but the disclosed technology is not limited thereto.

The pixel isolation pattern 113 may be disposed between the photoelectric conversion elements 112 of adjacent unit pixels (PXs) in the first substrate 111, and may thus electrically isolate the photoelectric conversion elements 112 from each other. The pixel isolation pattern 113 may be formed in a mesh shape when viewed in a plan view. The pixel isolation pattern 113 may include a deep trench isolation (DTI) structure in which an insulation material is buried in a pixel isolation trench that extends in a vertical direction (e.g., a direction toward the first front surface) from the first back surface of the first substrate 111. In this case, the insulation material may include a material such as the anti-reflection layer 114. For example, the insulation material may be formed to be buried in the pixel isolation trench to form the pixel isolation pattern 113, and may extend over the first back surface of the first substrate 111. In this case, the insulation layer formed over the first back surface of the first substrate 111 may serve as the anti-reflection layer 114.

The anti-reflection layer 114 may be formed between the first back surface of the first substrate 111 and the color filters 116 such that incident light can be incident on the photoelectric conversion elements 112 without being reflected from the first substrate 111. The anti-reflection layer 114 may include at least one of silicon nitride, silicon oxide, or silicon oxynitride.

The grid structure 115 may be formed between the color filters 116, and may thus prevent crosstalk between adjacent color filters. The grid structure 115 may include metal (e.g., tungsten).

The color filters 116 may be formed over the anti-reflection layer 114 in the pixel region (PXA). The color filters 116 may be arranged to correspond to the unit pixels (PXs), and may filter visible light from incident light. The color filters 116 may include red, green, or blue color filters (R, G, B) arranged in a Bayer pattern.

The over-coating layer 117 may operate as a planarization layer and configured to remove a step difference between the color filters 116, and may be formed over the color filters 116. The over-coating layer 117 may be formed of or include the same material as the microlenses 118. For example, the over-coating layer 117 may include a light transmissive photoresist.

The microlenses 118 may be formed over the over-coating layer 117 to correspond to the color filters 116. Each of the microlenses 118 may be formed in a convex shape having a predetermined radius of curvature (RoC) to converge incident light onto the photoelectric conversion element 112.

Pixel transistors 119 may be formed over the first front surface of the first substrate 111 so that the pixel transistors 119 are electrically coupled to the first metal interconnects 124. The pixel transistors 119 may be formed to correspond to the unit pixels (PXs) in the pixel region (PXA).

The pixel transistors 119 may generate pixel signals corresponding to the amount of photo-charges generated by the photoelectric conversion element 112 of the corresponding unit pixel (PX), and may output the pixel signals through the first metal interconnects 124. The pixel signals output from the pixel region (PXA) may be transferred to logic transistors 214 of the logic region (LA) through the first metal interconnects 124, the TSV structure 310, and second metal interconnects (224, 226). The pixel transistors 119 may include at least one of a transfer transistor, a reset transistor, a source follower transistor, and a select transistor.

The TSV structure 310 may be formed to be connected to the second metal interconnects 226 of the second interconnect layer 220 while penetrating the first stacked structure 100. The TSV structure 310 may electrically connect the metal interconnects 126 of the first interconnect layer 120 and the second metal interconnects 226 of the second interconnect layer 220. The TSV structure 310 may include a first TSV 312 conformally formed along an inner surface of a through hole 318, a second TSV 314 formed over the first TSV 312 within the through hole 318, and a passivation layer 316 formed to cover the first and second TSVs 312 and 314 while gap-filling the through hole 318.

The first TSV may extend toward the first back surface of the first substrate 111 and may be connected to the electrode pad 320. Each of the first TSV 312 and the second TSV 314 may include at least one of a metal, a metal silicide, or a metal compound. For example, the first TSV 312 may include tungsten (W), and the second TSV 314 may include aluminum (Al).

The passivation layer 316 may protect the TSVs 312 and 314 from the external environment (e.g., temperature, moisture, etc.), and may include a photoresist. For example, the passivation layer 316 may include the same photoresist for lenses as the over-coating layer 117. Alternatively, the passivation layer 316 may include a stacked structure in which an i-line photoresist is formed in the through hole 318 and a photoresist for lenses is formed thereon. The passivation layer 316 may be formed to entirely cover the TSV structure 310 while exposing an upper surface of the electrode pad 320 in the peripheral region (PERI).

Although FIG. 4 shows a structure in which the TSV structure 310 is coupled to the electrode pad (PAD), the TSV structure 310 may be formed to connect the metal interconnects 126 of the first stacked structure 100 to the second metal interconnects 226 of the second stacked structure 200 without being connected to the electrode pad (PAD). Thus, the TSV structure 310 may be used for electrical connection between the stacked structures 100 and 200 only inside the image sensing device rather than for connection to an external device.

The pad isolation pattern 330 may be disposed between the pixel region (PXA) and the electrode pad 320 in the first substrate 111 of the peripheral region (PERI) so as to isolate the pad region (PA) and the pixel region (PXA) from each other. The pad isolation pattern 330 may be formed in a region between the pixel region (PXA) and the electrode pad 320 to prevent noise generated in the peripheral region (PERI) from flowing into the pixel region (PXA). The pad isolation pattern 330 may penetrate the first substrate 111, and may be formed in a loop shape surrounding the pixel region (PXA) when viewed in a plan view.

The pad isolation pattern 330 may include a lower isolation pattern 330L and an upper isolation pattern 330U.

The lower isolation pattern 330L may include a trench isolation structure in which an insulation material is buried in a trench extending from the first front surface of the first substrate 111 toward the first back surface of the first substrate 111. For example, the lower isolation pattern 330L may include a shallow trench isolation (STI) structure. The lower isolation pattern 330L may be formed such that a bottom surface thereof is connected to the upper isolation patterns 330U. The lower isolation pattern 330L may be formed simultaneously with formation of a device isolation structure defining an active region in which the pixel transistors 119 are formed in the pixel region (PXA).

Although FIG. 4 illustrates an example case in which one lower isolation pattern 330L is connected to a plurality of upper isolation patterns 330U for convenience of description, other implementations are also possible. If necessary, the lower isolation patterns 330L may be separately formed to correspond to the upper isolation patterns 330U in a one-to-one correspondence.

The upper isolation pattern 330U may include a first upper isolation pattern 332 and a second upper isolation pattern 334.

The first upper isolation pattern 332 may include a trench isolation structure in which an insulation material is buried in a trench extending from the first back surface of the first substrate 111 toward the first front surface of the first substrate 111. For example, the first upper isolation pattern 332 may include a deep trench isolation (DTI) structure.

The first upper isolation pattern 332 may be formed to extend toward the first front surface by the same depth as the pixel isolation pattern 113. For example, the trench for forming the first upper isolation pattern 332 may be formed together with a trench for forming the pixel isolation pattern 113 in the pixel region (PXA). The first upper isolation pattern 332 may have a larger width than the pixel isolation pattern 113, and may be formed in a shape where the width thereof gradually decreases from the first back surface toward the first front surface of the first substrate 111.

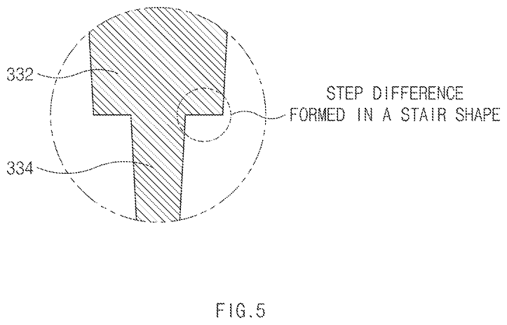

The second upper isolation pattern 334 may include a trench isolation structure in which an insulation material is buried in a trench extending from the bottom surface of the first upper isolation pattern 332 toward the first front surface. Here, the upper surface of the second upper isolation pattern 334 may be formed to have a smaller width than the bottom surface of the first upper isolation pattern 332, so that a step difference is created in a stair shape that is formed in a boundary surface (e.g., an interface) between the first upper isolation pattern 332 and the second upper isolation pattern 334 as shown in FIG. 5. The bottom surface of the second upper isolation pattern 334 may be in contact with a top surface of the lower isolation pattern 330L, or may be formed to extend to a predetermined depth at which the bottom surface of the second upper isolation pattern 334 is inserted into the lower isolation pattern 330L. The second upper isolation pattern 334 may be formed to have a smaller width than the bottom surface of the first upper isolation pattern 332, and may be formed in a shape where the width thereof gradually decreases toward the first front surface.

Although the embodiment of FIG. 4 has disclosed a pad isolation pattern having a double structure in which two upper isolation patterns 330U are located adjacent to each other, other implementations are also possible, and it should be noted that the number of upper isolation patterns 330U may be further increased as needed.

The first interconnect layer 120 may be formed under the first front surface of the first substrate 111, and may be formed to contact the second interconnect layer 220 of the second stacked structure 200. The first interconnect layer 120 may include a first interlayer insulation layer 122 and first metal interconnects 124 formed in the first interlayer insulation layer 122.

In the pixel region (PXA) and the peripheral region (PERI), the first interlayer insulation layer 122 may include insulation materials that are disposed among the pixel transistors 119, the TSV structure 310, and the first metal interconnects 124. The first interlayer insulation layer 122 may include at least one of silicon oxide, silicon nitride, and silicon oxynitride.

The first metal interconnects 124 may be formed in the first interlayer insulation layer 122 within the pixel region (PXA) and the peripheral region (PERI), and may electrically connect the pixel transistors 119 to the TSV structure 310. In addition, the first metal interconnects 124 may electrically interconnect the pixel transistors 119 within the pixel region (PXA). The first metal interconnects 124 may be formed in a multilayer structure.

In some implementations, a multi-layer image sensor includes an upper layer stacked on a lower layer and a through silicon via (TSV) structure that is electrically conductive and is configured to electrically connect circuits of the upper and lower layers to each other.

The second stacked structure 200 may include a second substrate layer 210 and a second interconnect layer 220.

The second substrate layer 210 may include a second substrate 212 and a plurality of logic transistors 214.

The second substrate 212 may include a second front surface and a second back surface opposite to the second front surface. The second front surface of the second substrate 212 may be a surface on which the logic transistors are formed, and may be in contact with the second interconnect layer 220. The second substrate 212 may include a semiconductor substrate such as the first substrate 111.

The logic transistors 214 may be formed at a second front surface of the second substrate 212 such that the logic transistors 214 can be coupled to the second metal interconnects 224. The logic transistors 214 may generate control signals to control operations of the unit pixels (PXs), and may process the pixel signals output from the unit pixels (PXs). For example, the logic transistors 214 may include transistors configured to construct the row driver 20, the CDS 30, the ADC 40, the output buffer 50, the column driver 60, and the timing controller 70 shown in FIG. 1. The logic transistors 214 may be formed in the logic region (LA) within the second substrate 212. The logic transistors 214 may receive pixel signals from the unit pixels (PXs) through the first metal interconnects 124, the TSV structure 310, and the second metal interconnects 224.

The second interconnect layer 220 may be formed over the second front surface of the second substrate 212, and may be formed to contact the first interconnect layer 120 of the first stacked structure 100. The second interconnect layer 220 may include a second interlayer insulation layer 222, and second metal interconnects 224 formed in the second interlayer insulation layer 222.

In the logic region (LA) and the peripheral region (PERI), the second interlayer insulation layer 222 may include insulation materials that are disposed among the logic transistors 214, the TSV structure 310, and the second metal interconnects 224. The second interlayer insulation layer 222 may include at least one of silicon oxide, silicon nitride, and silicon oxynitride.

The second metal interconnects 224 may be formed in the second interlayer insulation layer 222 within each of the logic region (LA) and the peripheral region (PERI), and may electrically connect the logic transistors 214 to the TSV structure 310. In addition, the second metal interconnects 224 may electrically connect the logic transistors 214 to each other within the logic region (LA). The second metal interconnects 224 may be formed in a multilayer structure. Of the metal interconnects, the second metal interconnects 226 contacting a lower end of the TSV structure 310 may be formed to be thicker than other metal interconnects.

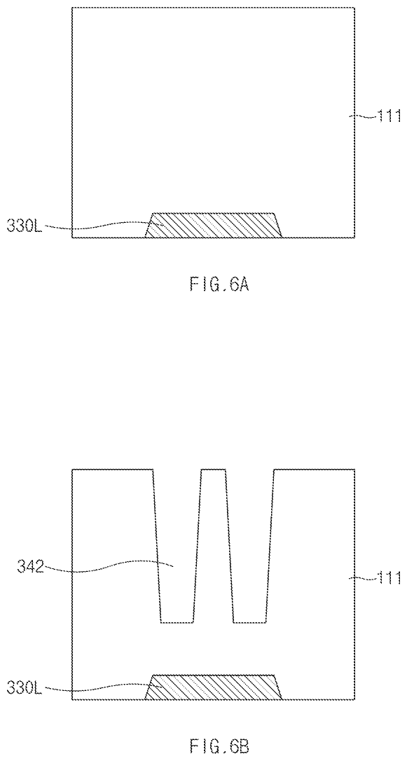

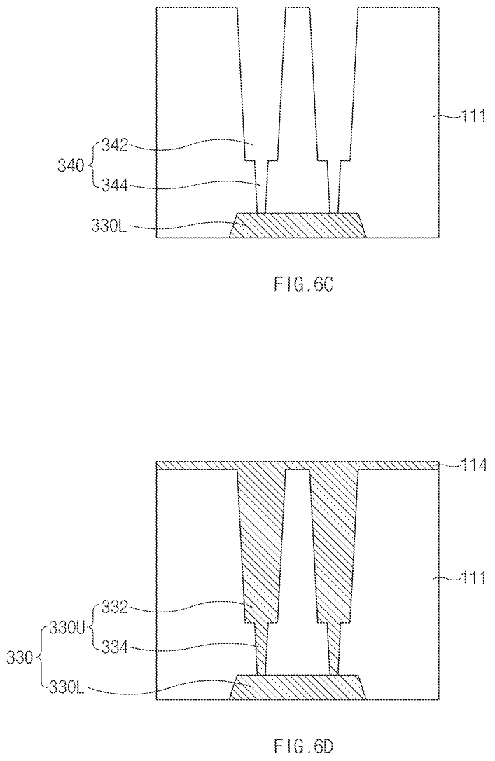

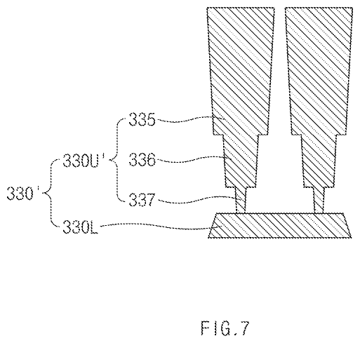

FIGS. 6A to 6D are cross-sectional views illustrating examples of a process for forming the pad isolation pattern shown in FIG. 4.

Referring to FIG. 6A, a trench etched to a predetermined depth from the first front surface of the first substrate 111 may be formed in the peripheral region (PERI), and may then be filled with an insulation material, resulting in formation of a lower isolation pattern 330L.

The lower isolation pattern 330L may include a shallow trench isolation (STI) structure, and may be formed simultaneously with formation of a device isolation structure defining an active region having the pixel transistors 119 in the pixel region (PXA).

Referring to FIG. 6B, a plurality of first trenches 342 etched to a predetermined depth from the first back surface of the first substrate 111 may be formed. The first trenches 342 may be used to form a pad isolation pattern configured to isolate the pixel region (PXA) and the pad region (PA) from each other, and may be formed between the pixel region (PXA) and the pad region (PA). For example, the first trenches 342 may be formed between the pixel region (PXA) and the pad region (PA) to surround the pixel region (PXA).

In some implementations, although the first trenches 342 are formed in a double structure in which the two first trenches 342 are arranged adjacent to each other for convenience of description, other implementations are also possible, and it should be noted that the number of such first trenches 342 may be increased or decreased as needed.

The first trenches 342 may be formed to have the same depth as the pixel isolation trenches for forming the pixel isolation pattern 113 in the pixel region (PXA). For example, the first trenches 342 may be formed simultaneously with formation of pixel isolation trenches in the pixel region (PXA).

Referring to FIG. 6C, the first substrate 111 may be further etched from the bottom surface of the first trenches 342 until the lower isolation pattern 330L is exposed, such that a plurality of second trenches 344 can be formed to connect the first trenches 342 to the lower isolation pattern 330L. For example, the first trench 342 and the second trench 344 connected to each other may be a through hole 340 for isolating (or separating) one pad that penetrates the first substrate 111 in a region where the lower isolation pattern 330L is formed.

In some implementations, a top surface of each of the second trenches 344 may be formed to have a smaller width than a bottom surface of each of the first trenches 342, so that the first trench 342 and the second trench 344 connected to each other are formed. A step difference in a stair shape may be formed in a boundary surface between the first trench 342 and the second trench 344. That is, a stepped shape may be formed in the boundary surface between the first trench 342 and the second trench 344.

Referring to FIG. 6D, an insulation material may be formed over the first back surface of the first substrate 111 to fill the through hole 340 for pad isolation, so that the upper isolation patterns 330U connected to the lower isolation pattern 330L can be formed.

In some implementations, each of the first trenches 342 is formed to have a larger width, whereas each of the second trenches 344 is formed to have a smaller width. In this way, the insulation material can be effectively provided into the second trenches 344 through the first trenches 342. As a result, the insulation material can be effectively formed in the second trenches 344 while avoiding forming voids in the second trenches 344.

A process of forming the insulation material in the through hole 340 may be performed together with the process of forming the pixel isolation pattern 113 by filling the pixel isolation trench with the insulation material within the pixel region (PXA). In this case, the insulation material formed over the first back surface of the first substrate 111 may serve as the anti-reflection layer 114.

When the pad isolation pattern is formed in the peripheral region (PERI) to isolate the pixel region (PXA) and the pad region (PA) from each other, a through hole formed to penetrate the first substrate 111 is formed, and the insulation material is buried in the through hole. Here, when forming the through hole extending from the first back surface toward the first front surface of the first substrate 111, a lower region (e.g., a region located close to the first front surface) of the through hole needs to be formed as narrow as possible so as to minimize the influence on the elements located on the first front surface of the first substrate 111. To this end, the through hole for forming the pad isolation pattern is generally formed through only one etching process for forming a trench having a small width and a deep depth.

However, when the insulation material is buried in such a through hole, the through hole is incompletely filled with the insulation material, resulting in a void formed in the through hole. In particular, since the lower region of the through hole has a smaller width, the void can be formed to extend to the end of the through hole. In such a case, cracks can be generated during the subsequent process and can be transferred to the opposite side (e.g., the first front surface) of the first substrate 111 through voids formed in the pad isolation pattern so that unexpected cracks may be formed in the lower isolation pattern 330L, thereby causing progressive defects (e.g., cracks are further generated in the interconnect layer 120). Therefore, when forming the pad isolation pattern penetrating the first substrate 111, it is desirable to prevent formation of voids, and it is necessary to prevent formation of voids in at least a portion adjacent to the first front surface.

In some embodiments of the disclosed technology, as described above, each of the second trenches 344 is formed to have a smaller width and each of the first trenches 342 is formed to have a larger width in a manner that the insulation material can flow well into the second trenches 344. As a result, the lower region of the upper isolation pattern 330U and the insulation material is completely buried in the lower region of the upper isolation pattern 330U, thereby preventing formation of voids.

FIG. 7 is a cross-sectional view illustrating an example structure of a pad isolation pattern 330′ based on some implementations of the disclosed technology.

Referring to FIG. 7, the pad isolation pattern 330′ may include a lower isolation pattern 330L and an upper isolation pattern 330U′. The upper isolation pattern 330U′ may include a first upper isolation pattern 335, a second upper isolation pattern 336, and a third upper isolation pattern 337.

The first upper isolation pattern 335 may have the same structure as the first upper isolation pattern 332 of the pad isolation pattern 330 described above.

The second upper isolation pattern 336 may include a trench isolation structure in which an insulation material is buried in a trench extending from the bottom surface of the first upper isolation pattern 335 toward the first front surface. Here, a top surface of the second upper isolation pattern 336 may be formed to have a smaller width than a bottom surface of the first upper isolation pattern 335, so that a step difference in a stair shape may be formed in a boundary surface between the first upper isolation pattern 335 and the second upper isolation pattern 336 as shown in FIG. 5. That is, a stepped shape may be formed in the boundary surface between the first upper isolation pattern 335 and the second upper isolation pattern 336, as shown in FIG. 5. In this case, the second upper isolation pattern 336 may be formed to a smaller depth than the second upper isolation pattern 334 of the above-described pad isolation pattern 330.

The third upper isolation pattern 337 may include a trench isolation structure in which an insulation material is buried in a trench extending from the bottom surface of the second upper isolation pattern 336 toward the first front surface. Here, a top surface of the third upper isolation pattern 337 may be formed to have a smaller width than the bottom surface of the second upper isolation pattern 336, so that a step difference formed in a stair shape (i.e., a stepped shape) may also be formed in a boundary surface between the second upper isolation pattern 336 and the third upper isolation pattern 337. The end portion of the third upper isolation pattern 337 may be formed to have a smaller width than the end portion of the second upper isolation pattern 334 of the pad isolation pattern 330 described above. A bottom surface of the third upper isolation pattern 337 may be in contact with the top surface of the lower isolation pattern 330L, or may be formed to extend to a predetermined depth at which the bottom surface of the third upper isolation pattern 337 is inserted into the lower isolation pattern 330L.

In some implementations, a lower end of the pad isolation pattern 330′ can be formed to have a smaller width than that of the above-described pad isolation pattern 330, and at the same time the insulation material can be completely buried in the lower end of the pad isolation pattern 330′.

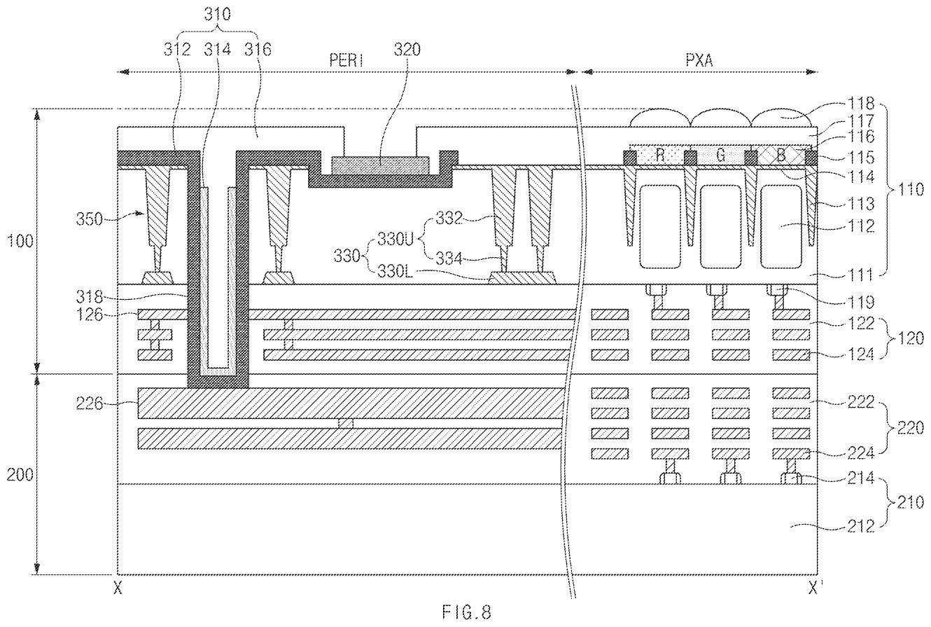

FIG. 8 is a cross-sectional view illustrating an example structure of a pad isolation pattern based on some implementations of the disclosed technology.

Referring to FIG. 8, the first stacked structure 100 may further include a TSV isolation pattern 350 that is formed to surround the TSV structure 310 while being spaced apart from the TSV structure 310.

The TSV isolation pattern 350 may have substantially the same structure as the above-described pad isolation pattern 330 except that only one upper isolation pattern is formed and a lower isolation pattern is formed in a size corresponding to the one upper isolation pattern 330U. For example, the upper isolation pattern of the TSV isolation pattern 350 may be formed to have a stepped shape like the above-described upper isolation patterns 330U or 330U′.

As is apparent from the above description, the image sensing device based on some implementations of the disclosed technology can prevent progressive defects that may occur in a process of forming an isolation structure and subsequent processes thereof by improving the isolation structure.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a semiconductor substrate including a first surface and a second surface facing or opposite to the first surface, and structured to include a pixel region in which photoelectric conversion elements are formed to correspond to unit pixels and a pad region that is located outside the pixel region while having an electrode pad;
a pixel isolation pattern disposed between the photoelectric conversion elements in the semiconductor substrate; and
a pad isolation pattern disposed between the pixel region and the pad region in the semiconductor substrate,
wherein the pad isolation pattern includes:
at least one first upper isolation pattern formed to extend from the first surface toward the second surface to have a same depth as the pixel isolation pattern; and
at least one second upper isolation pattern formed to extend from a bottom surface of the at least one first upper isolation pattern toward the second surface, wherein an upper surface of the at least one second upper isolation pattern has a smaller width than the bottom surface of the at least one first upper isolation pattern.

2. The image sensing device according to claim 1, wherein the pad isolation pattern further includes:
a lower isolation pattern formed to extend from the second surface of the semiconductor substrate toward the first surface of the semiconductor substrate, wherein a bottom surface of the lower isolation pattern is connected to the at least one second upper isolation pattern.

3. The image sensing device according to claim 2, wherein:
the lower isolation pattern of the pad isolation pattern is connected to two or more of the at least one second upper isolation pattern.

4. The image sensing device according to claim 2, wherein:
the pad isolation pattern is formed to penetrate the semiconductor substrate.

5. The image sensing device according to claim 1, wherein the pad isolation pattern further includes:
at least one third upper isolation pattern formed to extend from a bottom surface of the at least one second upper isolation pattern toward the second surface of the semiconductor substrate, wherein an upper surface of the at least one third upper isolation pattern has a smaller width than the bottom surface of the at least one second upper isolation pattern.

6. The image sensing device according to claim 5, wherein the pad isolation pattern further includes:
a lower isolation pattern formed to extend from the second surface of the semiconductor substrate toward the first surface of the semiconductor substrate, wherein a bottom surface of the lower isolation pattern is connected to the at least one third upper isolation pattern.

7. The image sensing device according to claim 6, wherein:
the lower isolation pattern of the pad isolation pattern is connected to two or more of the at least one third upper isolation pattern.

8. The image sensing device according to claim 1, wherein:
the pad isolation pattern is formed in a loop shape surrounding the pixel region.

9. The image sensing device according to claim 1, wherein:
the first and second upper isolation patterns are configured to include a same insulation material as the pixel isolation pattern.

10. The image sensing device according to claim 1, further comprising:
a through silicon via (TSV) structure disposed to penetrate the semiconductor substrate and connected to the electrode pad; and
a TSV isolation pattern disposed at both sides of the TSV structure.

11. The image sensing device according to claim 10, wherein:
a side surface of the TSV isolation pattern has at least one stepped shape.

12. The image sensing device according to claim 10, wherein the TSV structure includes:
a through hole formed to penetrate the semiconductor substrate;
a first TSV formed along an inner surface of the through hole and connected to the electrode pad;
a second TSV disposed over the first TSV within the through hole; and
a passivation layer disposed over the first TSV and the second TSV to fill the through hole while exposing a portion of the electrode pad.

13. An image sensing device comprising:
a semiconductor substrate structured to include a pixel region in which photoelectric conversion elements for photoelectric conversion of incident light are formed and a pad region that is located outside the pixel region while having an electrode pad;
a pixel isolation pattern vertically extending to a first depth in the semiconductor substrate and disposed between the photoelectric conversion elements; and
a pad isolation pattern vertically extending in the semiconductor substrate to a second depth greater than the first depth and disposed between the pixel region and the pad region, wherein the pad isolation pattern has a stepped shape at the first depth.

14. The image sensing device according to claim 13, wherein the pad isolation pattern includes:
at least one first upper isolation pattern formed to extend to the first depth in the semiconductor substrate from a first surface of the semiconductor substrate; and
at least one second upper isolation pattern formed to vertically extend from a bottom surface of the at least one first upper isolation pattern, wherein an upper surface of the at least one second upper isolation pattern has a smaller width than the bottom surface of the at least one first upper isolation pattern.

15. The image sensing device according to claim 14, wherein the pad isolation pattern further includes:
a lower isolation pattern formed to extend from a second surface of the semiconductor substrate toward the first surface of the semiconductor substrate, wherein the second surface is opposite to the first surface, wherein a bottom surface of the lower isolation pattern is connected to the at least one second upper isolation pattern.

16. The image sensing device according to claim 15, wherein:
the lower isolation pattern of the pad isolation pattern is connected to two or more of the at least one second upper isolation pattern.

17. The image sensing device according to claim 14, wherein the pad isolation pattern further includes:
at least one third upper isolation pattern formed to vertically extend from a bottom surface of the at least one second upper isolation pattern, wherein an upper surface of the at least one third upper isolation pattern has a smaller width than the bottom surface of the at least one second upper isolation pattern.

18. The image sensing device according to claim 17, wherein the pad isolation pattern further includes:
a lower isolation pattern formed to extend from a second surface of the semiconductor substrate toward the first surface of the semiconductor substrate, wherein the second surface is opposite to the first surface, wherein a bottom surface of the lower isolation pattern is connected to the at least one third upper isolation pattern.

19. The image sensing device according to claim 18, wherein:
the lower isolation pattern of the pad isolation pattern is connected to two or more of the at least one third upper isolation pattern.
